(19) United States
(12) Patent Application Publication
(10) Pub. No.: US 2025/0125226 A1
(43) Pub. Date: Apr. 17, 2025

(54) ELECTRONIC COMPONENT EMBEDDED MODULE AND METHOD OF MANUFACTURING ELECTRONIC COMPONENT EMBEDDED MODULE

(71) Applicant: SAMSUNG ELECTRONICS CO., LTD., Suwon-si (KR)

(72) Inventors: Ryuichiro TOMINAGA, Yokohama (JP); Mitsuhiro TOMIKAWA, Yokohama (JP); Takashi KARIYA, Yokohama (JP); Toshiki FURUTANI, Yokohama (JP)

(73) Assignee: SAMSUNG ELECTRONICS CO., LTD., Suwon-si (KR)

(21) Appl. No.: 18/770,168

(22) Filed: Jul. 11, 2024

(30) Foreign Application Priority Data
Oct. 17, 2023 (JP) 2023-178589
Jan. 4, 2024 (KR) 10-2024-0001730

(51) Int. Cl. H01L 23/49; H01L 23/00; H01L 25/10

(52) U.S. Cl. CPC H01L 23/49; H01L 24/16; H01L 24/32; H01L 24/73; H01L 25/105; H01L 2224/16227; H01L 2224/32225; H01L 2224/73204

(57) ABSTRACT

An electronic component embedded module may include a hole diameter defining layer, an electronic component, and an insulation layer. The hole diameter defining layer may include an inner wall, an outer wall, a front surface intersecting with the inner wall and the outer wall, and a rear surface. The electronic component may include a first terminal surface facing the rear surface of the hole diameter defining layer, and a first terminal electrode on the first terminal surface. The insulation layer is between the first terminal surface and the rear surface, covers the outer wall, and includes a step with respect to the front surface around the front surface. A connection hole may extend from the inner wall of the hole diameter defining layer to the first terminal electrode through the insulation layer.

### CROSS-REFERENCE TO RELATED APPLICATIONS

This application is based on and claims priority under 35 U.S.C. § 119 to Japanese Patent Application No. 2023-178589, filed on Oct. 17, 2023, in the Japan Patent Office, and Korean Patent Application No. 10-2024-0001730, filed on Jan. 4, 2024, in the Korean Intellectual Property Office, the disclosures of which are incorporated by reference herein in their entirety.

### BACKGROUND

### 1. Technical Field

Embodiments of the present disclosure relate to an electronic component embedded module and a method of manufacturing the electronic component embedded module.

### 2. Brief Description of Background Art

Recently, electronic component embedded modules having embedded therein electronic components are being spotlighted. An electronic component embedded module functions, for example, as an interposer that interconnects a semiconductor element with a mounting substrate.

### SUMMARY

In such an electronic component embedded module, it is desirable to reduce the hole diameter of a connection hole.

Embodiments of the present disclosure provide an electronic component embedded module that may reduce hole diameters of connection holes and a method of manufacturing the electronic component embedded module.

According to embodiments of the present disclosure, an electronic component embedded module may be provided and include a hole diameter defining layer, an electronic component, and an insulation layer. The hole diameter defining layer may include an inner wall, an outer wall, a front surface intersecting with the inner wall and the outer wall, and a rear surface facing away from the front surface. The electronic component may include a first terminal surface facing the rear surface of the hole diameter defining layer, and a first terminal electrode on the first terminal surface. The insulation layer is between the first terminal surface and the rear surface of the hole diameter defining layer, covers the outer wall of the hole diameter defining layer, and includes a step with respect to the front surface of the hole diameter defining layer around the front surface of the hole diameter defining layer. A connection hole may extend from the inner wall of the hole diameter defining layer to the first terminal electrode through the insulation layer.

According to embodiments of the present disclosure, an electronic component embedded module may be provided and include: a hole diameter defining layer; a metal film; an electronic component; and an insulation layer. The hole diameter defining layer may include an inner wall, an outer wall, a front surface intersecting with the inner wall and the outer wall, and a rear surface facing away from the front surface. The electronic component may include: a first terminal surface facing the rear surface of the hole diameter defining layer; and a first terminal electrode on the first terminal surface. The insulation layer is between the first terminal surface and the rear surface of the hole diameter defining layer and covers the outer wall of the hole diameter defining layer. The metal film is on the front surface of the hole diameter defining layer and includes an opening. A connection hole may extend from the opening to the first terminal electrode and through the hole diameter defining layer and the insulation layer.

According to embodiments of the present disclosure, an electronic device may be provided and include: a mounting substrate; an electronic component embedded module on the mounting substrate; and a semiconductor element on the electronic component embedded module. The electronic component embedded module may include: a hole diameter defining layer including an inner wall, an outer wall, a front surface intersecting with the inner wall and the outer wall, and a rear surface facing away from the front surface; an electronic component including: a first terminal surface facing the rear surface of the hole diameter defining layer; and a first terminal electrode on the first terminal surface; an insulation layer between the first terminal surface and the rear surface of the hole diameter defining layer, covering the outer wall of the hole diameter defining layer, and including a step with respect to the front surface of the hole diameter defining layer around the front surface of the hole diameter defining layer. A connection hole may extend from the inner wall of the hole diameter defining layer to the first terminal electrode through the insulation layer.

### BRIEF DESCRIPTION OF THE DRAWINGS

Embodiments of the present disclosure will be more clearly understood from the following detailed description taken in conjunction with the accompanying drawings in which:

FIG. 1 is a cross-sectional view of an electronic device including an electronic component embedded module, according to an embodiment;

FIG. 2 is an enlarged cross-sectional view of a vicinity of a hole diameter defining layer shown in FIG. 1;

FIG. 3 is a diagram showing an example of a planar configuration of the hole diameter defining layer shown in FIG. 2;

FIGS. 4 to 20 are cross-sectional views of a method of manufacturing the electronic device shown in FIG. 1;

FIG. 21 is a cross-sectional view of an electronic component embedded module, according to a modified example;

FIG. 22 is a cross-sectional view of an electronic component embedded module, according to another modified example;

FIG. 23 is a cross-sectional view of an electronic component embedded module, according to another modified example; and

FIG. 24 is a cross-sectional view of an electronic component embedded module, according to another modified example.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

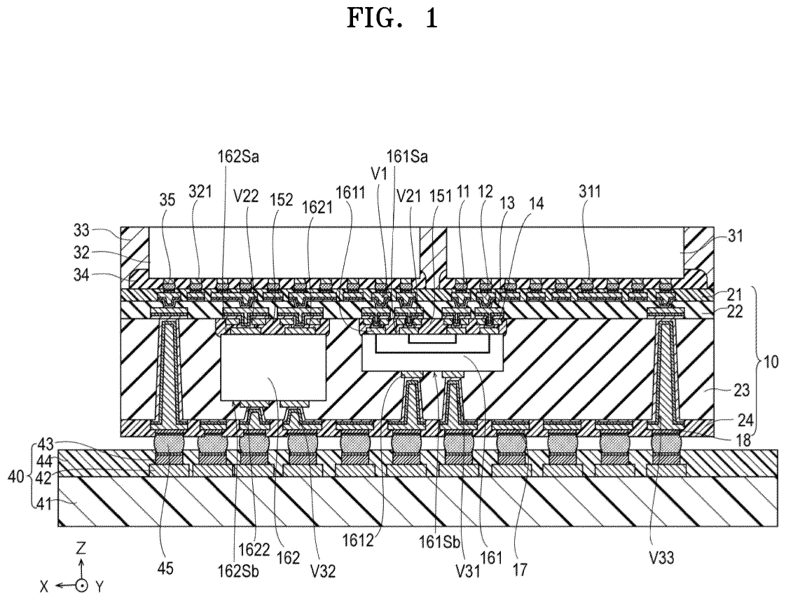

FIG. 1 illustrates an electronic device including an electronic component embedded module 10, according to an embodiment.

Referring to FIG. 1, the electronic device may include, for example, the electronic component embedded module 10, a semiconductor element 31, a semiconductor element 32, and a mounting substrate 40. The electronic component embedded module 10 may function as an interposer that interconnects the semiconductor element 31 and the semiconductor element 32 with the mounting substrate 40. In the electronic device, the mounting substrate 40, the electronic component embedded module 10, and the semiconductor element 31 and the semiconductor element 32 are stacked in the order stated. In the descriptions below, a direction in which the mounting substrate 40, the electronic component embedded module 10, and the semiconductor element 31 and the semiconductor element 32 are stacked is referred to as the Z direction, a direction orthogonal to the Z direction is referred to as the X direction, and a direction orthogonal to the Z direction and the X direction is referred to as the Y direction.

The semiconductor element 31 and the semiconductor element 32 may be, for example, semiconductor chips each having a certain function. The semiconductor element 31 and the semiconductor element 32 may be, for example, integrated circuit (IC) chips or memories. The semiconductor element 31 includes a plurality of electrodes 311 on a certain plane (e.g., the XY plane). The semiconductor element 32 includes a plurality of electrodes 321 on a certain plane (e.g., the XY plane). For example, the electronic device may further include an encapsulation layer 33, an underfill member 34, and a plurality of bumps 35 near the semiconductor element 31 and the semiconductor element 32.

The plurality of bumps 35 may electrically connect each of the electrodes 311 and the electrodes 321 to the electronic component embedded module 10. The bumps 35 may include, for example, a solder material. The underfill member 34 may be provided between the semiconductor element 31 and the electronic component embedded module 10, and between the semiconductor element 32 and the electronic component embedded module 10. For example, the space between the bumps 35 adjacent to each other may be filled with the underfill member 34. The encapsulation layer 33 may be stacked on the underfill member 34. The encapsulation layer 33 may cover the periphery of the semiconductor element 31 and the semiconductor element 32. The encapsulation layer 33 and the underfill member 34 may include, for example, a resin material.

The mounting substrate 40 may be, for example, a semiconductor package substrate or a main board. The mounting substrate 40 may include, for example, a base member 41, a wiring layer 42, electrodes 43, and a solder resist layer 44.

The mounting substrate 40 may be electrically connected to the electronic component embedded module 10 through a plurality of bumps 45. The plurality of bumps 45 may be provided on the electrodes 43. For example, the spacing between the bumps 45 adjacent to each other may be larger than the spacing between the bumps 35 adjacent to each other. The bumps 45 may include, for example, a solder material.

### Configuration of Electronic Component Embedded Module 10

The electronic component embedded module 10 may include, for example, a first substrate electrode 11, a relay conductor layer 12, a first conductor layer 13, a hole diameter defining layer 14, an adhesive layer 151, an adhesive layer 152, an electronic component 161, an electronic component 162, a second conductor layer 17, a second substrate electrode 18, a first solder resist layer 21, a first insulation layer 22, a second insulation layer 23, and a second solder resist layer 24. Here, the adhesive layer 151 and the adhesive layer 152 correspond to an example of an insulation layer of an embodiment of the present disclosure.

In the electronic component embedded module 10, the first solder resist layer 21, the first insulation layer 22, the second insulation layer 23, and the second solder resist layer 24 may be stacked in the order stated in the Z direction. For example, the first solder resist layer 21, the first insulation layer 22, the second insulation layer 23, and the second solder resist layer 24 may be arranged in the order stated from the semiconductor element 31 and the semiconductor element 32. The first solder resist layer 21 and the second solder resist layer 24 may include, for example, an organic insulation material such as epoxy resin, phenol resin, and acrylic resin. The first solder resist layer 21 and the second solder resist layer 24 may also include fillers.

The first insulation layer 22 and the second insulation layer 23 may include, for example, an organic insulation material such as epoxy resin, phenolic resin, acrylic resin, polyimide resin, and liquid crystal polymer. The first insulation layer 22 and the second insulation layer 23 may also include fillers. The first insulation layer 22 and the second insulation layer 23 may also include an inorganic insulation material.

The first substrate electrode 11 may be disposed on one cross-section of the electronic component embedded module 10 in the Z direction (e.g., the XY plane). The second substrate electrode 18 may be disposed on the other cross-section of the electronic component embedded module 10 in the Z direction (e.g., the XY plane). For example, the first substrate electrode 11 may be provided in an opening of the first solder resist layer 21. The second substrate electrode 18 may be provided, for example, in an opening of the second solder resist layer 24. The electronic component embedded module 10 may have, for example, a plurality of the first substrate electrode 11 and a plurality of the second substrate electrode 18.

For example, the plurality of the first substrate electrode 11 may be provided at positions corresponding to the electrodes 311 of the semiconductor element 31 and the electrodes 321 of the semiconductor element 32, respectively. For example, the plurality of the second substrate electrode 18 may be provided at positions respectively corresponding to the electrodes 43 of the mounting substrate 40. The plurality of the first substrate electrode 11 may be electrically connected to the electrodes 311 and the electrodes 321 through the bumps 35. The plurality of the second substrate electrode 18 may be electrically connected to the electrodes 43 through the bumps 45. For example, the first substrate electrode 11 and the second substrate electrode 18 may each include a conductive metal material such as gold, copper, nickel, or tin. A material constituting the first substrate electrode 11 may be different from a material constituting the second substrate electrode 18. The first substrate electrode 11 and the second substrate electrode 18 may each include, for example, a plating film.

For example, the relay conductor layer 12 may be in contact with each of the plurality of the first substrate electrode 11. For example, the plurality of the first substrate electrode 11 may be provided in a selective region of the top surface of the relay conductor layer 12.

For example, the relay conductor layer 12 may be disposed in a certain pattern on the top surface of the first insulation layer 22. For example, the top surface and the side surfaces of the relay conductor layer 12 may be covered with the first solder resist layer 21. The relay conductor layer 12 may include a conductive metal material, e.g., gold, platinum, palladium, silver, copper, aluminum, cobalt, titanium, chromium, nickel, tungsten, iron, tin, indium or zinc. The relay conductor layer 12 may include, for example, copper. The relay conductor layer 12 may include, for example, a plating film.

The first conductor layer 13 may electrically interconnect the relay conductor layer 12 to the electronic component 161 and the electronic component 162 (more specifically, a first terminal electrode 1611 and a first terminal electrode 1621, as described below). The first conductor layer 13 may include a conductive metal material such as, for example, gold, platinum, palladium, silver, copper, aluminum, cobalt, titanium, chromium, nickel, tungsten, iron, tin, indium, or zinc. For example, the first conductor layer 13 may be disposed in a certain pattern on the second insulation layer 23. For example, the first conductor layer 13 may be provided at a position that overlaps the electronic component 161 and the electronic component 162 on a plane (XY plane). For example, the top surface and the side surfaces of the first conductor layer 13 may be covered with the first insulation layer 22.

A connection hole V1 reaching the top surface of the first conductor layer 13 may be formed in the first insulation layer 22. For example, the relay conductor layer 12 may be provided in the connection hole V1. As a result, the first conductor layer 13 and the first substrate electrode 11 may be electrically connected to each other. The relay conductor layer 12 may be connected to the first conductor layer 13 through a seed layer. The seed layer may include, for example, an adhesion film containing titanium and a conductive film containing copper.

The hole diameter defining layer 14 may be disposed between the first conductor layer 13 and the electronic component 161 and between the first conductor layer 13 and the electronic component 162, for example. Detailed description of the hole diameter defining layer 14 is given below.

The adhesive layer 151 and the adhesive layer 152 may be provided between the first insulation layer 22 and the electronic component 161 and the electronic component 162. The adhesive layer 151 may be provided between the first insulation layer 22 and the electronic component 161, and the adhesive layer 152 may be provided between the first insulation layer 22 and the electronic component 162. The adhesive layer 151 and the adhesive layer 152 may adhere the electronic component 161 and the electronic component 162 to the first insulation layer 22, respectively. The periphery of the adhesive layer 151 and the adhesive layer 152 may be covered with the second insulation layer 23.

The adhesive layer 151 and the adhesive layer 152 may include, for example, an organic insulation material such as epoxy resin, phenolic resin, acrylic resin, polyimide resin, and liquid crystal polymer. The adhesive layer 151 and the adhesive layer 152 may also include fillers. The linear expansion coefficient of the adhesive layer 151 and the adhesive layer 152 may be lower than the linear expansion coefficient of the second insulation layer 23. As a result, the warpage of the electronic component embedded module 10 may be suppressed. The thermal conductivity of the adhesive layer 151 and the adhesive layer 152 may be higher than the thermal conductivity of the second insulation layer 23. As a result, the heat dissipation of the electronic component embedded module 10 may be improved.

The electronic component 161 and the electronic component 162 may be buried in the second insulation layer 23. The electronic component 161 and the electronic component 162 have certain functions, such as ICs, bridges, condensers, capacitors, inductors, coils, thermistors, resistors, and fuses. The electronic component 161 and the electronic component 162 may be, for example, semiconductor chips. As the electronic component embedded module 10 includes the electronic component 161 and the electronic component 162, a desired function may be provided to an interposer interconnecting the semiconductor element 31 and the semiconductor element 32 with the mounting substrate 40. Therefore, miniaturization and higher functionality of electronic devices may be realized. The materials constituting the electronic component 161 and the electronic component 162 may be different from the material constituting the first insulation layer 22. The elastic modulus of the electronic component 161 and the electronic component 162 may be different from the elastic modulus of the first insulation layer 22. For example, the thickness (size in the Z direction) of the electronic component 161 may be different from the thickness of the electronic component 162.

The electronic component 161 may have, for example, a first terminal surface 161Sa and a second terminal surface 161Sb facing away from each other in the Z direction. The electronic component 162 may have, for example, a first terminal surface 162Sa and a second terminal surface 162Sb facing away from each other in the Z direction. For example, the first terminal surface 161Sa and the first terminal surface 162Sa may be arranged parallel in one XY plane, and the second terminal surface 161Sb and the second terminal surface 162Sb may be arranged parallel in another XY plane. For example, the first terminal surface 161Sa and the first terminal surface 162Sa may be arranged toward the first insulation layer 22, and the second terminal surface 161Sb and the second terminal surface 162Sb may be arranged toward the second solder resist layer 24. The adhesive layer 151 may be provided between the first terminal surface 161Sa and the first insulation layer 22. The adhesive layer 152 may be provided between the first terminal surface 162Sa and the first insulation layer 22.

A first terminal electrode 1611 may be provided on the first terminal surface 161Sa of the electronic component 161, and a second terminal electrode 1612 may be provided on the second terminal surface 161Sb of the electronic component 161. The electronic component 161 may include, for example, a plurality of the first terminal electrode 1611 and a plurality of the second terminal electrode 1612. A first terminal electrode 1621 may be provided on the first terminal surface 162Sa of the electronic component 162, and a second terminal electrode 1622 may be provided on the second terminal surface 162Sb. The electronic component 162 may include, for example, a plurality of the first terminal electrode 1621 and a plurality of the second terminal electrode 1622.

A connection hole V21 reaching the surface of the first terminal electrode 1611 may be formed in the adhesive layer 151. The first conductor layer 13 and the connection hole V21 may be connected to each other. For example, a portion of the first conductor layer 13 may be in the connection hole V21. As a result, the first terminal electrode 1611 and the first substrate electrode 11 may be electrically connected to each other through the relay conductor layer 12 and the first conductor layer 13.

A connection hole V22 reaching the top surface of the first terminal electrode 1621 may be formed in the adhesive layer 152. The first conductor layer 13 and the connection hole V22 may be connected to each other. For example, a portion of the first conductor layer 13 may be in the connection hole V22. As a result, the first terminal electrode 1621 and the first substrate electrode 11 may be electrically connected to each other through the relay conductor layer 12 and the first conductor layer 13.

For example, the second conductor layer 17 may be in contact with each of the plurality of the second substrate electrode 18. For example, the second substrate electrode 18 may be provided in a select region of the top surface of the second conductor layer 17. For example, the second conductor layer 17 may be disposed in a certain pattern on the bottom surface of the second insulation layer 23. For example, the top surface and the side surfaces of the second conductor layer 17 may be covered with the second solder resist layer 24. The second conductor layer 17 may include a conductive metal material, e.g., gold, platinum, palladium, silver, copper, aluminum, cobalt, titanium, chromium, nickel, tungsten, iron, tin, indium or zinc. The second conductor layer 17 may include, for example, copper. The second conductor layer 17 may include, for example, a plating film.

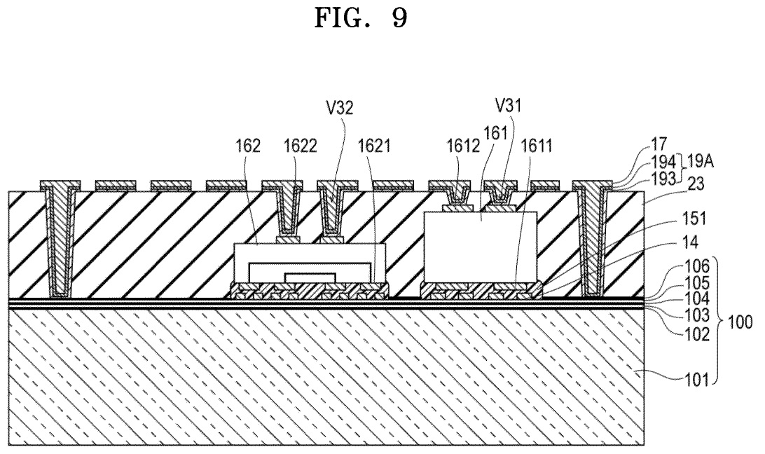

A connection hole V31 and a connection hole V32 respectively reaching second terminal electrode 1612 and the second terminal electrode 1622 may be formed in the second insulation layer 23 in which the electronic component 161 and the electronic component 162 are embedded. The second conductor layer 17 may be connected to the connection hole V31 and the connection hole V32. For example, portions of the second conductor layer 17 may be in the connection hole V31 and the connection hole V32. As a result, the second terminal electrode 1622 and the second substrate electrode 18 may be electrically connected to each other through the second conductor layer 17. The second conductor layer 17 may also be connected to the second terminal electrode 1612 and the second terminal electrode 1622 through a seed layer (e.g., a seed layer 19A of FIG. 9). In this regard, the electronic component embedded module 10 has the connection hole V31 and the connection hole V32 respectively reaching the second terminal surface 161Sb and the second terminal surface 162Sb, in addition to the connection hole V21 and the connection hole V22 respectively reaching the first terminal surface 161Sa and the first terminal surface 162Sa. As a result, for example, the power supplied to the electronic component 161 and the electronic component 162 may be improved. Also, heat generated by the electronic component 161 and the electronic component 162 may be dissipated more effectively.

The volume of the connection hole V31 and the connection hole V32 may be greater than the volume of the connection hole V1. Therefore, signal integrity and power integrity may be improved. Also, the heat dissipation of the electronic component embedded module 10 may be improved.

For example, a connection hole V33 penetrating through the second insulation layer 23 in the Z direction and reaching the first conductor layer 13 may be formed in the second insulation layer 23. The second conductor layer 17 and the connection hole V33 may be connected to each other. For example, a portion of the second conductor layer 17 may be in the connection hole V33. As a result, the first substrate electrode 11 and the second substrate electrode 18 are electrically connected to each other through the first conductor layer 13 and the second conductor layer 17. A pillar or the like may be provided in the second insulation layer 23 instead of the connection hole V33. The second conductor layer 17 may also be connected to the first conductor layer 13 through a seed layer (e.g., the seed layer 19A of FIG. 9).

### Configuration of Hole Diameter Defining Layer 14

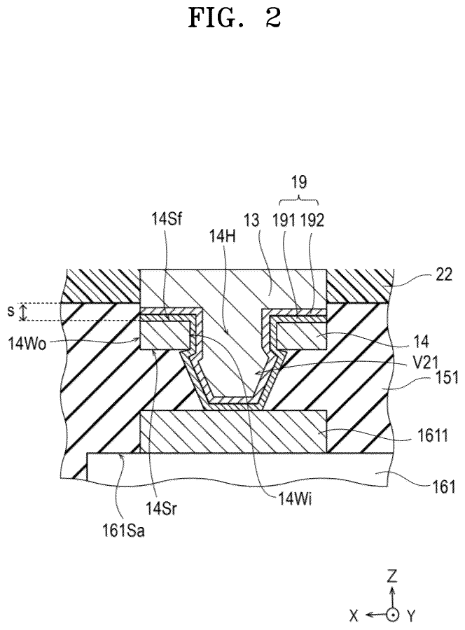

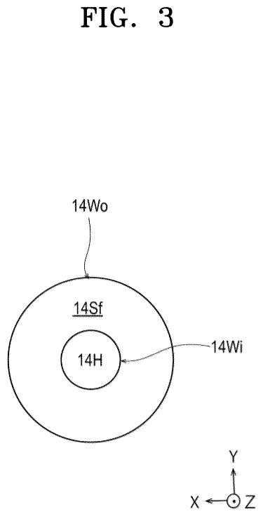

FIG. 2 is an enlarged view of the vicinity of the hole diameter defining layer 14 shown in FIG. 1. FIG. 3 shows an example of the plane (XY plane) configuration of the hole diameter defining layer 14 shown in FIG. 2. FIG. 2 illustrates the hole diameter defining layer 14 disposed near the electronic component 161. For example, the hole diameter defining layer 14 disposed near the electronic component 162 also has the same configuration.

Referring to FIGS. 2 and 3, the hole diameter defining layer 14 may be disposed, for example, at a position opposite to the first terminal electrode 1611. The hole diameter defining layer 14 may define the hole diameter of the connection hole V21 formed in the adhesive layer 151. Detailed descriptions thereof are given below. According to the present embodiment, since the electronic component embedded module 10 has the hole diameter defining layer 14, the hole diameter of the connection hole V21 may be reduced.

The hole diameter defining layer 14 has, for example, a front surface 14Sf and a rear surface 14Sr facing away from each other in the Z direction. The front surface 14Sf and the rear surface 14Sr may extend parallel to the XY plane, for example. The front surface 14Sf may be disposed toward the first insulation layer 22, and the rear surface 14Sr may be disposed toward the first terminal surface 161Sa. The adhesive layer 151 may be provided between the rear surface 14Sr and the first terminal surface 161Sa. The front surface 14Sf may not be covered with the adhesive layer 151. In other words, the front surface 14Sf may be exposed from the adhesive layer 151.

The hole diameter defining layer 14 has a circular or elliptical shape on the XY plane. For example, a through hole 14H penetrating from the front surface 14Sf to the rear surface 14Sr may be formed in the central portion of the hole diameter defining layer 14. The through hole 14H may have, for example, a circular or elliptical shape on the XY plane. The hole diameter of the through hole 14H may be, for example, from about 5 μm to about 50 μm. By forming the through hole 14H having the above-stated hole diameter, the connection hole V21 that achieves both the above-stated characteristics and the connection reliability may be formed.

The hole diameter defining layer 14 may have an inner wall 14Wi along the through hole 14H and an outer wall 14Wo along the outer edge of the hole diameter defining layer 14. The inner wall 14Wi and the outer wall 14Wo may extend in a direction crossing the front surface 14Sf and the rear surface 14Sr. The outer wall 14Wo may be covered with the adhesive layer 151. The adhesive layer 151 may have a step s with respect to the front surface 14Sf around the front surface 14Sf. For example, the adhesive layer 151 around the front surface 14Sf may protrude from the front surface 14Sf.

The connection hole V21 may reach the first terminal electrode 1611 from the inner wall 14Wi of the hole diameter defining layer 14 through the adhesive layer 151. In other words, a connection hole V21 may be formed in the adhesive layer 151, according to the shape of the inner wall 14Wi of the hole diameter defining layer 14. Therefore, by adjusting the hole diameter of the through hole 14H formed in the hole diameter defining layer 14, the hole diameter of the connection hole V21 may be reduced. The hole diameter of the connection hole V21 may be, for example, from about 5 μm to about 50 μm.

For example, the hole diameter of the connection hole V21 may gradually decrease in a direction from the rear surface 14Sr toward the first terminal electrode 1611. In other words, the connection hole V21 has a tapered shape. The maximum hole diameter of the connection hole V21 may be greater than the maximum hole diameter of the hole diameter defining layer 14, for example.

The maximum hole diameter (outer diameter) of the connection hole V21 may be, for example, greater than the maximum hole diameter of the through hole 14H by from about 1 μm to about 20 μm. The hole diameter of the connection hole V21 may be maximized, for example, near the rear surface 14Sr. The connection hole V21 having such a shape may be formed, for example, through laser beam irradiation.

For example, a seed layer 19 may be provided in the connection hole V21 together with the first conductor layer 13. The seed layer 19 may be provided along the inner wall 14Wi and the wall surface of the connection hole V21. The first conductor layer 13 may be electrically connected to the first terminal electrode 1611 through the seed layer 19.

The seed layer 19 may include, for example, an adhesion film 191 and a conductive film 192. The adhesion film 191 and the conductive film 192 may each include a conductive metal material, e.g., gold, platinum, palladium, silver, copper, aluminum, cobalt, titanium, chromium, nickel, tungsten, iron, tin, indium or zinc. The adhesion film 191 and the conductive film 192 may include at least one from among copper, aluminum, titanium, and chromium. The adhesion film 191 may include titanium, and the conductive film 192 may include copper. Therefore, the adhesion of the seed layer 19 may be maintained and the thickness of the seed layer 19 may be suppressed. The front surface 14Sf and the inner wall 14Wi of the hole diameter defining layer 14 may be covered with, for example, the seed layer 19.

The thickness (size in the Z direction) of the hole diameter defining layer 14 may be, for example, from about 2 um to about 10 um. The hole diameter defining layer 14 may include, for example, a conductive metal such as copper. The hole diameter defining layer 14 may be formed through electrolytic plating. In other words, the hole diameter defining layer 14 may include a plating film. As a result, the hole diameter of the through hole 14H may be easily controlled, and thus the connection hole V21 with the desired hole diameter may be easily formed.

### Method of Manufacturing Electronic Device

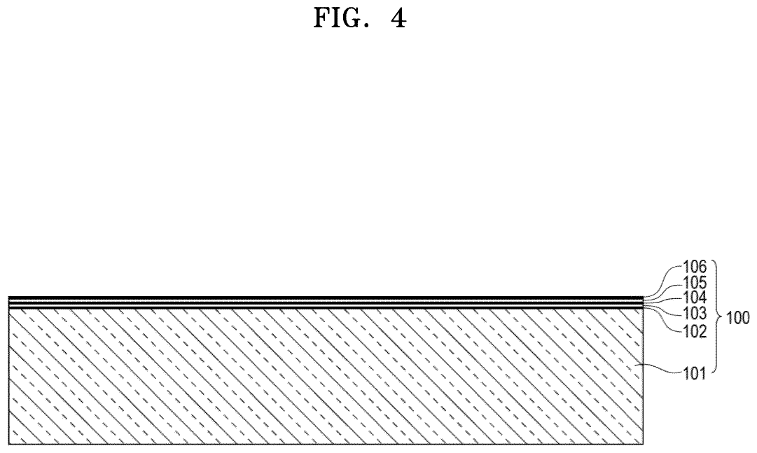

Next, an example of a method of manufacturing an electronic device is described with reference to FIGS. 4 to 20. FIGS. 4 to 20 are diagrams showing a method of manufacturing an electronic device, according to an embodiment.

Referring to FIG. 4, first, a support substrate 100 is prepared. The support substrate 100 may include, for example, a support body 101, a first adhesion layer 102, a second adhesion layer 103, a peeling layer 104, a first seed layer 105, and a second seed layer 106. For example, the support body 101 may include a plate-like member including at least one from among glass, silicon (Si), Stainless Used Steel (SUS), ferrite, alumina, and prepreg. Considering the thermal expansion coefficient and surface smoothness, the support body 101 may include glass. In the support substrate 100, the first adhesion layer 102, the second adhesion layer 103, the peeling layer 104, the first seed layer 105, and the second seed layer 106 may be stacked in the order stated on the support body 101.

The first adhesion layer 102, the second adhesion layer 103, the first seed layer 105, and the second seed layer 106 may each include a conductive metal such as gold, platinum, palladium, silver, copper, aluminum, cobalt, titanium, and chromium, nickel, tungsten, iron, tin, indium, or zinc. In terms of interlayer adhesion, the first adhesion layer 102 and the first seed layer 105 may include titanium. Considering conductivity and cost, the second adhesion layer 103 and the second seed layer 106 may include copper. The peeling layer 104 may include, for example, an inorganic material and copper. The first adhesion layer 102, the second adhesion layer 103, the first seed layer 105, and the second seed layer 106 may be formed by using, for example, a metal foil press method, a plating method, or a sputtering method. The support substrate 100 may include, for example, a High Resolution De-bondable Panel (HRDP, registered trademark).

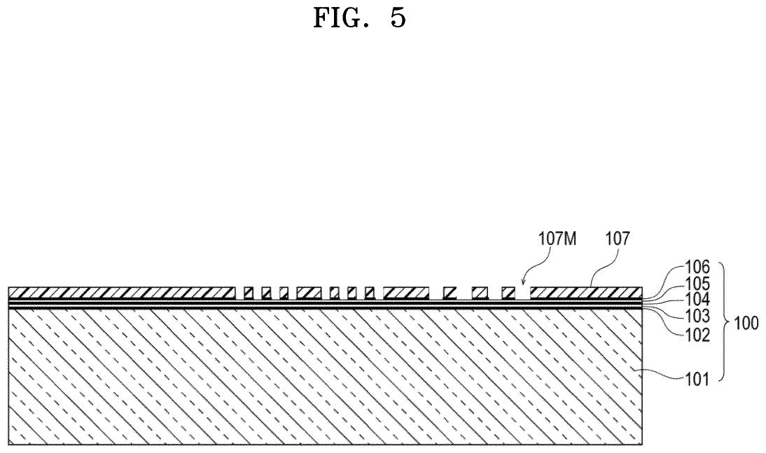

Referring to FIG. 5, next, a resist film 107 is disposed on the second seed layer 106, and at least one opening 107M is formed in the resist film 107. For example, each of the at least one opening 107M may be formed in an annular shape, as described with reference to FIG. 3. The at least one opening 107M is formed by using, for example, a photolithography method.

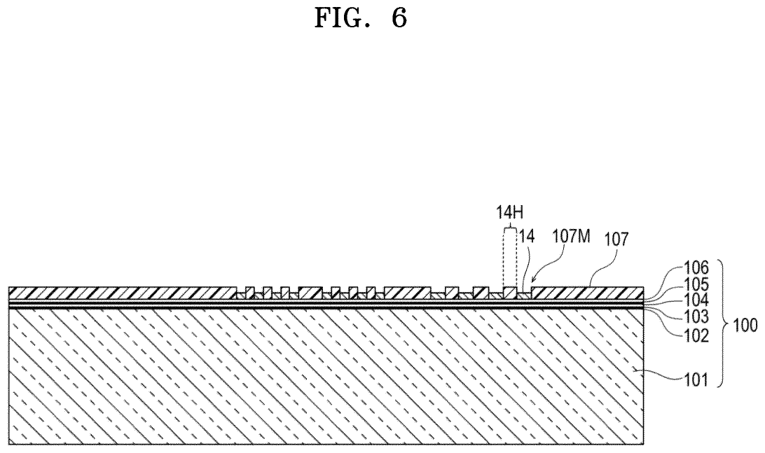

Referring to FIG. 6, after the at least one opening 107M is formed in the resist film 107, the hole diameter defining layer 14 is formed by using the at least one opening 107M. The hole diameter defining layer 14 may be formed by, for example, plating and growing copper in the at least one opening 107M by using an electrolytic plating method. Charges are supplied to the first seed layer 105 and the second seed layer 106 through the at least one opening 107M, and thus a metal such as copper may be plated and grown. Therefore, the hole diameter defining layer 14 having the through hole 14H may be formed. After the hole diameter defining layer 14 is formed, the resist film 107 may be removed.

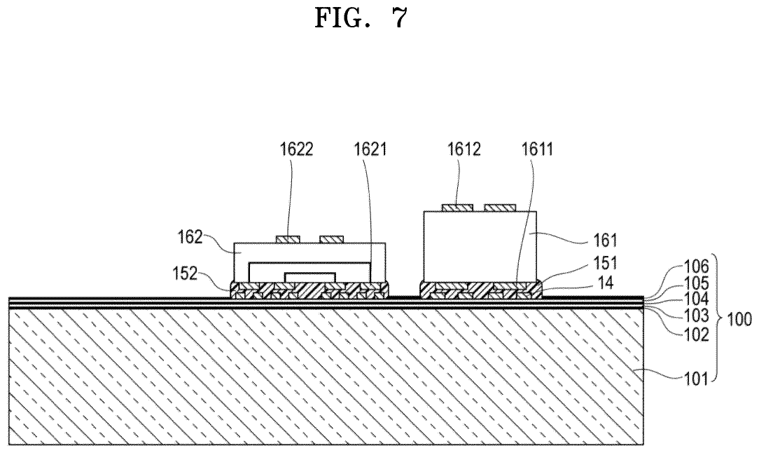

Referring to FIG. 7, the electronic component 161 and the electronic component 162 are mounted on the support substrate 100 such that the main surface of the support substrate 100 and the first terminal surfaces (e.g., the first terminal surface 161Sa and the first terminal surface 162Sa) face each other. That is, the electronic component 161 and the electronic component 162 may be mounted on the support substrate 100 in a face-down manner. Therefore, the plurality of electronic components (e.g., the electronic component 161 and the electronic component 162) having different thicknesses may be easily mounted. Also, alignment precision may be improved.

In the process of mounting the electronic component 161 and the electronic component 162, the first terminal electrode 1611 and the first terminal electrode 1621 are arranged at positions opposite to the hole diameter defining layer 14. The electronic component 161 and the electronic component 162 may be adhered to the support substrate 100 by using the adhesive layer 151 and the adhesive layer 152. The adhesive layer 151 and the adhesive layer 152 may be provided on the first terminal surface 161Sa of the electronic component 161 and the first terminal surface 162Sa of the electronic component 162, or on the support substrate 100 (more specifically, on the second seed layer 106). The adhesive layer 151 and the adhesive layer 152 may be in any form, such as a paste-type or a film-type, but, according to an embodiment, paste-type adhesive layers may be used.

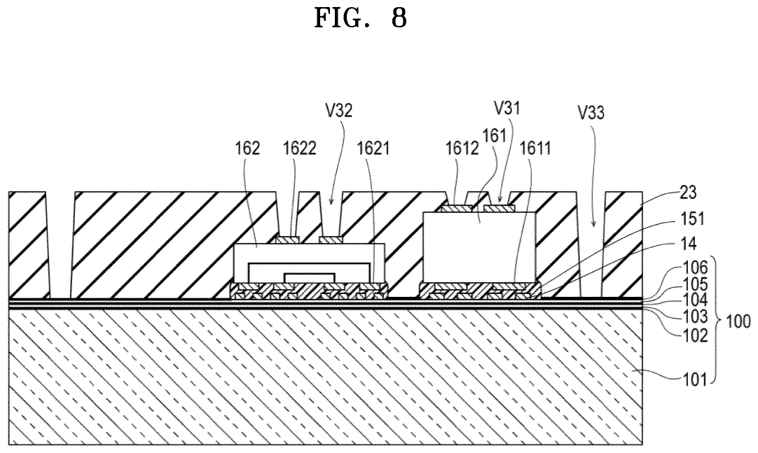

Referring to FIG. 8, after the electronic component 161 and the electronic component 162 are mounted on the support substrate 100, the second insulation layer 23 is formed on the support substrate 100. At this time, the connection hole V31 and the connection hole V32, that reach the second terminal electrode 1612 of the electronic component 161 and the second terminal electrode 1622 of the electronic component 162 from the top surface of the second insulation layer 23, and the connection hole V33, that penetrates the second insulation layer 23 in the thickness-wise direction, are formed in the second insulation layer 23. The second insulation layer 23 may be formed by providing an organic insulation material on the support substrate 100 by using, for example, a film lamination method or a spin coating method. By forming the second insulation layer 23 by using a film lamination method, the second insulation layer 23 with high surface flatness may be formed. The connection hole V31, the connection hole V32, and the connection hole V33 may be formed through laser processing or photolithography after the second insulation layer 23 is formed.

Referring to FIG. 9, after the connection hole V31, the connection hole V32, and the connection hole V33 are formed in the second insulation layer 23, the second conductor layer 17 is formed on the second insulation layer 23 and in the connection hole V31, the connection hole V32, and the connection hole V33. The second conductor layer 17 may be formed by using, for example, a semi-additive method.

For example, the semi-additive method may be implemented as follows. First, the seed layer 19A is formed on the second insulation layer 23 and in the connection hole V31, the connection hole V32, and the connection hole V33. The seed layer 19A may include, for example, an adhesion film 193 and a conductive film 194. For example, after the adhesion film 193 is formed, the conductive film 194 may be formed. The adhesion film 193 and the conductive film 194 may include, for example, a conductive metal material such as titanium, aluminum, and copper. The adhesion film 193 may include titanium, and the conductive film 194 may include copper. The seed layer 19A may be formed by using, for example, an electroless plating method, a sputtering method, a chemical vapor deposition (CVD) method, or an Atomic Layer Deposition (ALD) method. The seed layer 19A may be formed by using a sputtering method. After the seed layer 19A is formed, a resist film is formed, and an opening is formed in the resist film. A conductive metal material is plated and grown in the opening of the resist film. As a result, the second conductor layer 17 is formed in the opening of the resist film. Thereafter, the resist film is removed. The seed layer 19A exposed from the second conductor layer 17 may be removed by using, for example, an etching method.

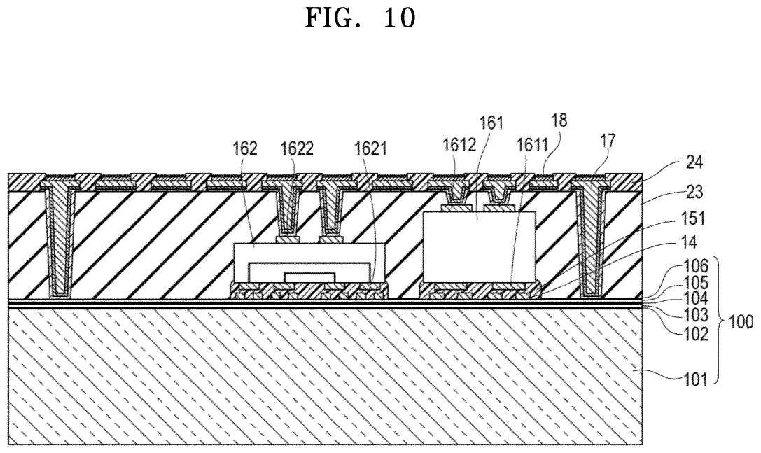

Referring to FIG. 10, after the second conductor layer 17 is formed, the second solder resist layer 24 and the second substrate electrode 18 are formed in the order stated. For example, after the second solder resist layer 24 is formed on the second insulation layer 23 to cover the second conductor layer 17, an opening may be formed in the second solder resist layer 24. The opening of the second solder resist layer 24 is formed at a position corresponding to the second conductor layer 17. The second solder resist layer 24 may be formed by using, for example, a photolithography method or a printing method. The second substrate electrode 18 is formed in the opening of the second solder resist layer 24. The second substrate electrode 18 may be formed by using, for example, an electroless plating method or an electrolytic plating method.

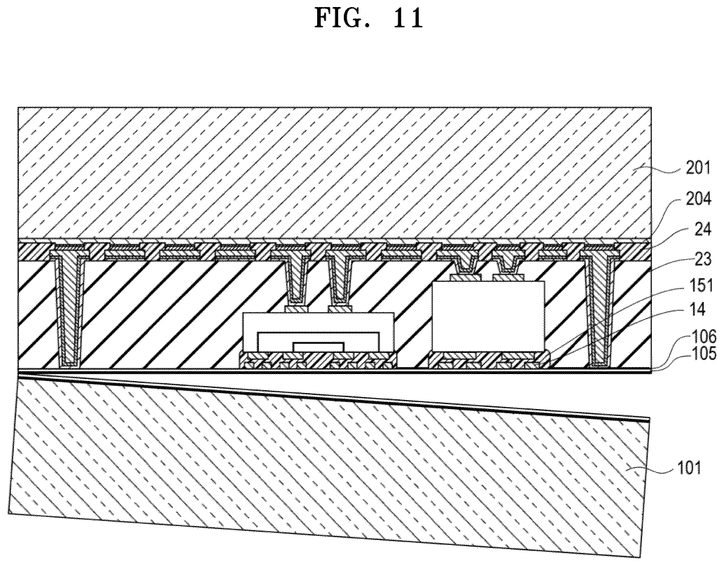

Referring to FIG. 11, after the second substrate electrode 18 is formed, a support body 201 is bonded to the second solder resist layer 24 through a peeling layer 204. The support body 201 is, for example, a plate-like member and may include the same material as the material of the support body 101. The support body 201 may include, for example, glass. The peeling layer 204 may include, for example, epoxy resin or acrylic resin. A metal film including titanium, copper, or nickel may be provided between the second solder resist layer 24 and the peeling layer 204. For example, after the support body 201 is attached to the second solder resist layer 24, the support body 101 may be removed. For example, the peeling layer 104 and the support body 101 may be peeled off from the first seed layer 105 by irradiating the peeling layer 104 with a laser beam or an ultraviolet (UV) ray. For example, the support body 101 may be peeled off by reducing the adhesion between the peeling layer 104 and the first seed layer 105 by using a chemical reaction with a chemical. Alternatively, the support body 101 may be peeled off by physically applying force to the support body 101.

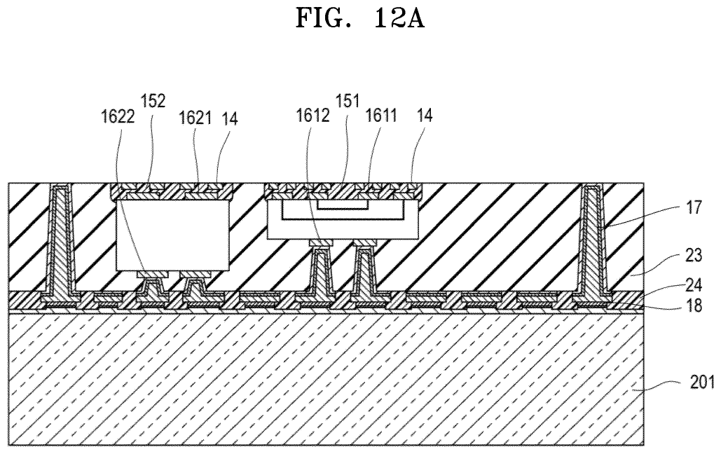

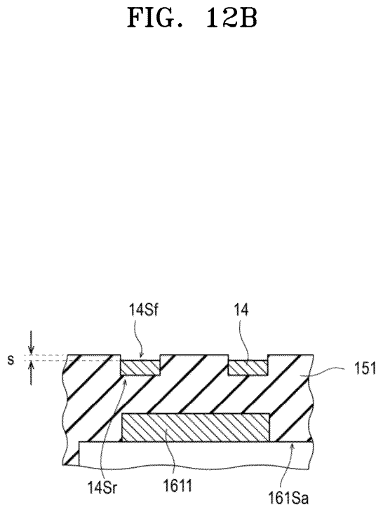

Referring to FIGS. 12A and 12B, after removing the support body 101 (see FIG. 11), the first seed layer 105 (see FIG. 11) and the second seed layer 106 (see FIG. 11) are removed. The first seed layer 105 (see FIG. 11) and the second seed layer 106 (see FIG. 11) may be removed through, for example, chemical etching using chemicals.

FIG. 12A shows the process after removal of the first seed layer 105 (see FIG. 11) and the second seed layer 106 (see FIG. 11), and FIG. 12B is an enlarged view of the vicinity of the hole diameter defining layer 14 shown in FIG. 12A. After performing the process of removing the first seed layer 105 (see FIG. 11) and the second seed layer 106 (see FIG. 11), a step between the front surface 14Sf and the adhesive layer 151 is formed around the front surface 14Sf of the hole diameter defining layer 14.

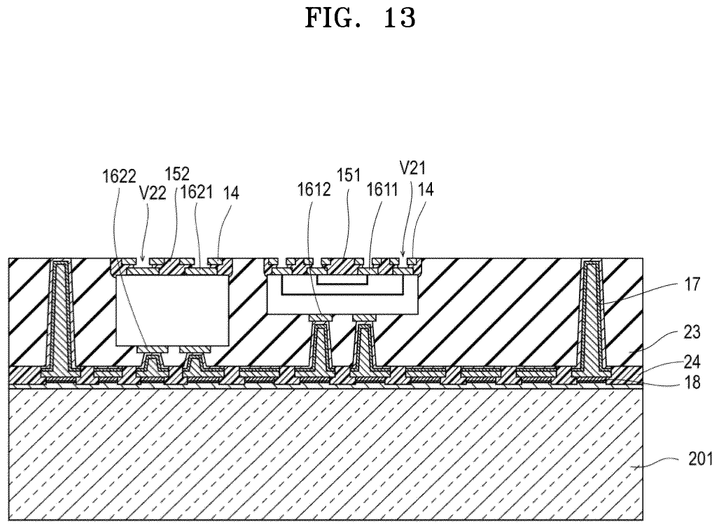

Referring to FIG. 13, after the first seed layer 105 (see FIG. 11) and the second seed layer 106 (see FIG. 11) are removed, the connection hole V21 and the connection hole V22 are formed. The connection hole V21 and the connection hole V22 may be formed by, for example, removing the adhesive layer 151 and the adhesive layer 152 along the inner wall 14Wi of the hole diameter defining layer 14 until the first terminal electrode 1611 and the first terminal electrode 1621 are exposed. Here, since the hole diameter defining layer 14 functions as a mask, the hole diameters of the connection hole V21 and the connection hole V22 are unlikely increased. Therefore, the connection hole V21 and the connection hole V22 with smaller hole diameters may be formed. The connection hole V21 and the connection hole V22 may be formed through, for example, plasma irradiation or laser beam irradiation. The connection hole V21 and the connection hole V22 may be formed through carbon dioxide (CO2) laser beam irradiation. After the laser beam irradiation to the connection hole V21 and the connection hole V22, for example, desmear treatment may be applied to the connection hole V21 and the connection hole V22.

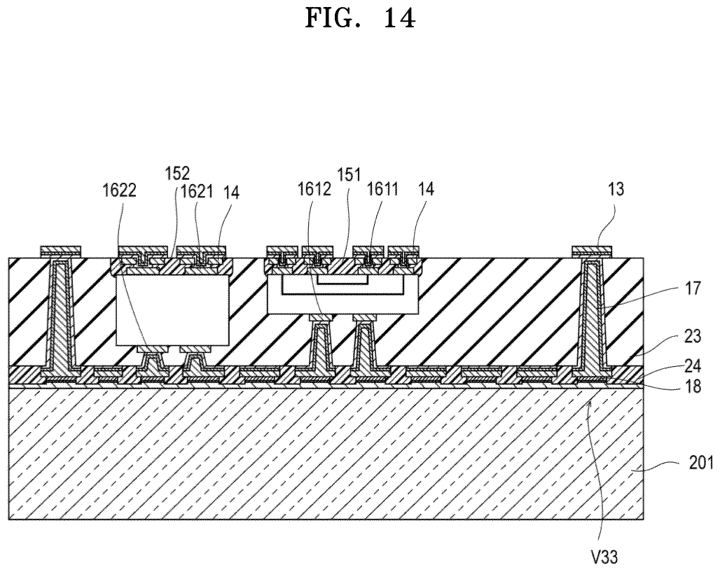

Referring to FIG. 14, next, the first conductor layer 13 is formed on the second insulation layer 23. For example, the first conductor layer 13 may be formed in the connection hole V21 and the connection hole V22 (see FIG. 13) and, at the same time, the first conductor layer 13 may be formed at a position corresponding to the connection hole V33. For example, the first conductor layer 13 may be formed in the same regard as the second conductor layer 17. In detail, after the seed layer 19 (see FIG. 2) is formed, the first conductor layer 13 may be formed by using an electrolytic plating method. The seed layer 19 may be formed by using, for example, an electroless plating method, a sputtering method, a CVD method, or an ALD method. The seed layer 19 may be formed by using a sputtering method.

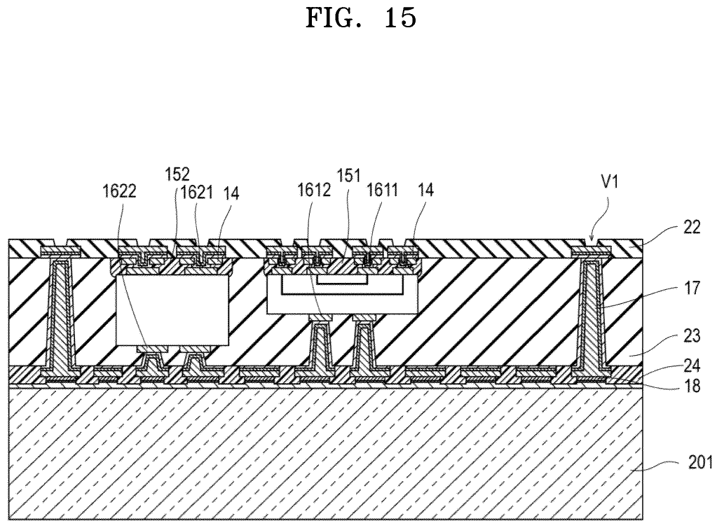

Referring to FIG. 15, after the first conductor layer 13 is formed, the first insulation layer 22 is formed on the second insulation layer 23 to cover the first conductor layer 13. At this time, the connection hole V1 reaching the first conductor layer 13 from the top surface of the first insulation layer 22 is formed in the first insulation layer 22. The first insulation layer 22 and the connection hole V1 may be formed in the same regards as the second insulation layer 23 and the connection holes (e.g., the connection hole V31, the connection hole V32, and the connection hole V33 of FIG. 8), respectively.

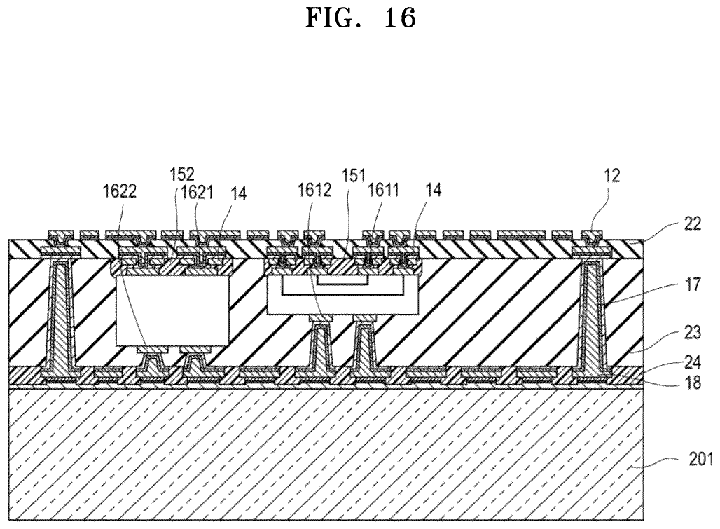

Referring to FIG. 16, next, the relay conductor layer 12 is formed on the first insulation layer 22. At this time, the relay conductor layer 12 and the inside of the connection hole V1 (see FIG. 15) may be connected to each other. For example, the relay conductor layer 12 may be formed in the same regard as the second conductor layer 17. In detail, after a seed layer is formed, the relay conductor layer 12 may be formed by using an electrolytic plating method.

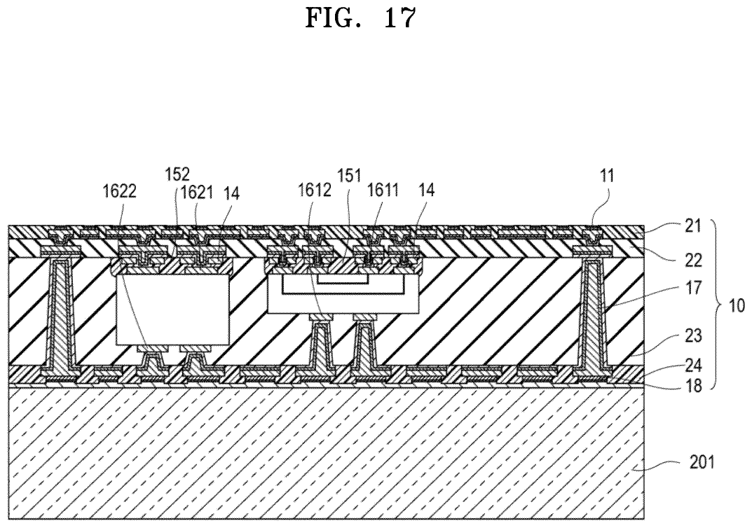

Referring to FIG. 17, the first solder resist layer 21 and the first substrate electrode 11 are sequentially formed. As a result, the electronic component embedded module 10 is formed. The first solder resist layer 21 and the first substrate electrode 11 may be formed in the same regards as the second solder resist layer 24 and the second substrate electrode 18, respectively.

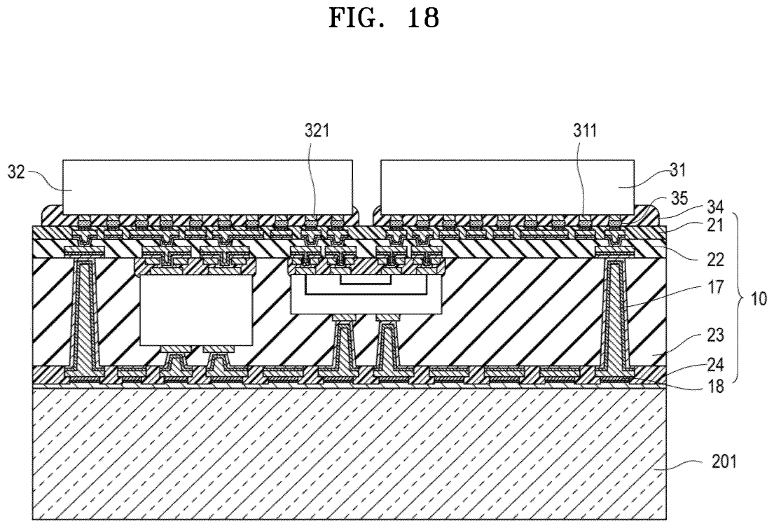

Referring to FIG. 18, next, the semiconductor element 31 and the semiconductor element 32 are mounted on the electronic component embedded module 10. At this time, the plurality of the electrode 311 of the semiconductor element 31 and the plurality of the electrode 321 of the semiconductor element 32 are electrically connected to the plurality of the first substrate electrode 11 of the electronic component embedded module 10 through the bumps 35. The underfill member 34 is formed between the semiconductor elements (e.g., the semiconductor element 31 and the semiconductor element 32) and the electronic component embedded module 10.

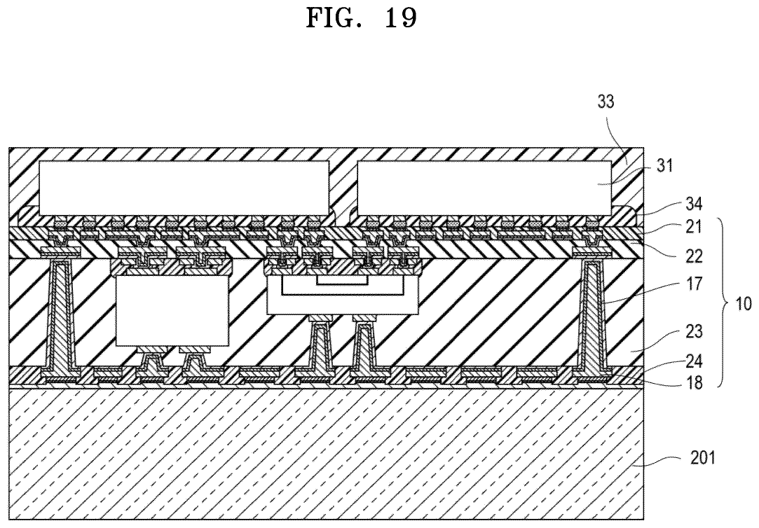

Referring to FIG. 19, next, the encapsulation layer 33 is formed to cover the semiconductor element 31 and the semiconductor element 32. For example, the thickness of the encapsulation layer 33 may be adjusted through polishing or the like.

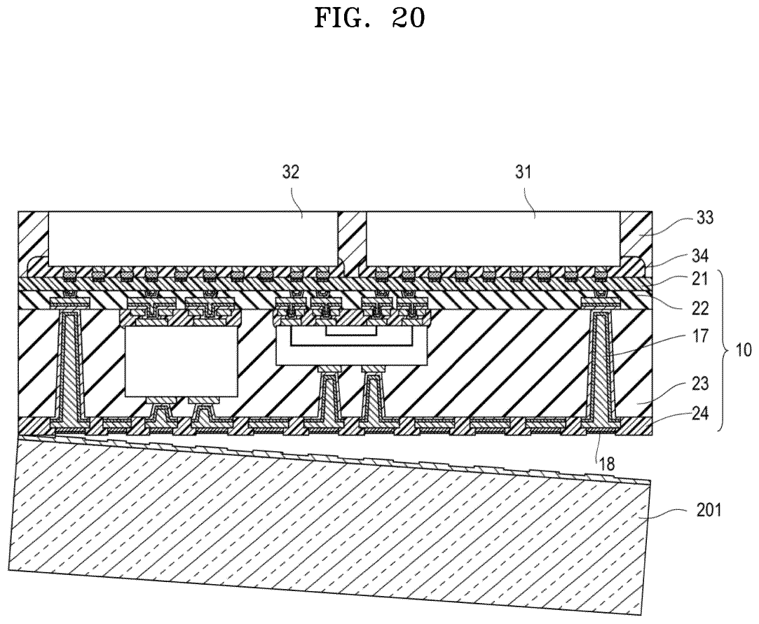

Referring to FIG. 20, the support body 201 is removed. For example, the support body 201 may be removed by peeling off the support body 201 from the electronic component embedded module 10. The support body 201 may be removed by using the same method as the support body 101 (see FIG. 11).

Thereafter, the mounting substrate 40 (see FIG. 1) is connected to the electronic component embedded module 10. For example, the electrode 43 (see FIG. 1) of the mounting substrate 40 (see FIG. 1) may be electrically connected to the second substrate electrode 18 of the electronic component embedded module 10 through the bump 45 (see FIG. 1). For example, an electronic device may be manufactured in this regard.

### Effect of Electronic Component Embedded Module 10

In the electronic component embedded module 10 according to an embodiment of the present disclosure, the hole diameter defining layer 14 having the inner wall 14Wi may be provided. The connection hole V21 and the connection hole V22 may be formed in the adhesive layer 151 and the adhesive layer 152 by using the inner wall 14Wi of the hole diameter defining layer 14. Therefore, the connection hole V21 and the connection hole V22 may be formed according to the shape of the inner wall 14Wi of the hole diameter defining layer 14. For example, when the hole diameter of the through hole 14H of the hole diameter defining layer 14 is about 5 μm, the connection hole V21 and the connection hole V22 each having the hole diameter of about 5 μm may be formed. Therefore, the hole diameters of the connection hole V21 and the connection hole V22 may be reduced.

Also, in the electronic component embedded module 10, the hole diameter defining layer 14 may be formed before the adhesive layer 151 and the adhesive layer 152 are formed. Therefore, the thickness of the electronic component embedded module 10 may be reduced. Also, the surface flatness of the first insulation layer 22 may be maintained, and thus a fine line may be formed.

Also, in the electronic component embedded module 10, the hole diameter defining layer 14 may be formed by using an electrolytic plating method. Therefore, it becomes easy to accurately control the hole diameter of the through hole 14H, (i.e., the shape of the inner wall 14Wi), and thus the connection hole V21 and the connection hole V22 having a desired hole diameter may be formed. For example, a method of forming a connection hole by using a copper foil formed on the front surface of an insulation layer may also be considered. At this time, for example, an opening may be formed in the copper foil by using an etching method. A connection hole may be formed in an adhesive layer through the opening of the copper foil. However, according to this method, since the opening is formed in the copper foil by using an etching method, the opening may easily be enlarged, and thus it becomes impossible to control the size of the opening. Therefore, the hole diameter of the connection hole also increases. The shape of the inner wall 14Wi may be accurately controlled by forming the hole diameter defining layer 14 by using an electrolytic plating method. Therefore, the connection hole V21 and the connection hole V22 with smaller hole diameters may be formed.

Also, the copper foil is thick and has high surface roughness. The thickness of the copper foil is, for example, about 5 μm, and the surface roughness Rz of the copper foil is, for example, about 1 μm or higher. In an electronic component embedded module having such a copper foil, fine lines may not be formed. On the other hand, in the electronic component embedded module 10 according to an embodiment of the present disclosure, it is not necessary to form a copper foil. Therefore, for example, a fine line with L (line)/S (space) of about 2/2 μm may be formed.

As described above, in the electronic component embedded module 10 according to an embodiment of the present disclosure, the connection hole V21 and the connection hole V22 are formed in the adhesive layer 151 and the adhesive layer 152 by using the inner wall 14Wi of the hole diameter defining layer 14. Therefore, the connection hole V21 and the connection hole V22 may be formed according to the shape of the inner wall 14Wi of the hole diameter defining layer 14. Therefore, the hole diameters of the connection hole V21 and the connection hole V22 may be reduced.

Hereinafter, a modified example of the electronic component embedded module 10 according to the above-stated embodiment will be described. Hereinafter, to avoid repeated descriptions, repeated descriptions of components identical to those of the electronic component embedded module 10 according to the above-stated embodiment are omitted.

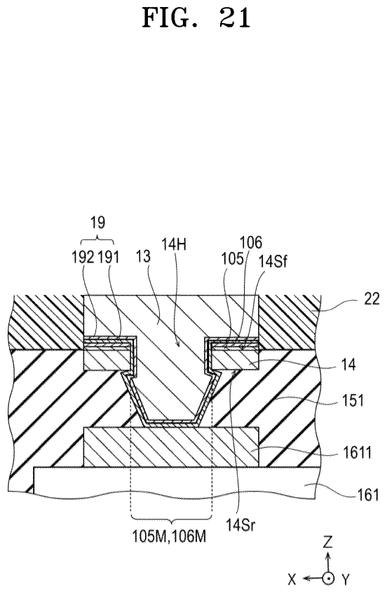

FIG. 21 shows an example of the configuration near the hole diameter defining layer 14 of the electronic component embedded module 10, according to a modified example. FIG. 21 corresponds to FIG. 2 showing the electronic component embedded module 10 of the above-stated embodiment. In the electronic component embedded module 10, the first seed layer 105 and the second seed layer 106 are arranged in the order stated on the front surface 14Sf of the hole diameter defining layer 14. Except for this point, the electronic component embedded module 10 according to the modified example has the same configuration as the electronic component embedded module 10 described in the above-stated embodiment. Here, the first seed layer 105 and the second seed layer 106 correspond to one specific example of metal films of an embodiment of the present disclosure.

Referring to FIG. 21, an opening 105M may be formed in the first seed layer 105 and an opening 106M may be formed in the second seed layer 106. The opening 105M and the opening 106M may be formed to penetrate the first seed layer 105 and the second seed layer 106 in the thickness-wise direction (Z direction). The opening 105M and the opening 106M may be formed at positions that overlap the through hole 14H of the hole diameter defining layer 14 when viewed on a plane (XY plane). Each of the opening 105M and the opening 106M has a diameter that is substantially identical to the hole diameter of the through hole 14H. The first seed layer 105 and the second seed layer 106 may each include at least one from among copper, titanium, and chromium. The first seed layer 105 may include titanium, and the second seed layer 106 may include copper. The thickness of each of the first seed layer 105 and the second seed layer 106 may be, for example, from about 0.05 μm to about 5 μm. The thickness of each of the first seed layer 105 and the second seed layer 106 may be less than the thickness of the hole diameter defining layer 14.

For example, the first seed layer 105 and the second seed layer 106 may be formed as follows. First, as described with reference to FIG. 11, the support body 201 may be bonded to the second solder resist layer 24 in the same regard as described in the above-stated embodiment, and then the support body 101 may be removed. Thereafter, the connection hole V21 and the connection hole V22 may be formed without removing the first seed layer 105 and the second seed layer 106. Therefore, the opening 105M and the opening 106M may be formed in the first seed layer 105 and the second seed layer 106. In other words, the connection hole V21 and the connection hole V22 reaching the first terminal electrode 1611 and the first terminal electrode 1621 from the opening 105M and the opening 106M through the inner wall 14Wi of the hole diameter defining layer 14 and the adhesive layers (e.g., the adhesive layer 151 and the adhesive layer 152) may be formed. At this time, for example, around the front surface 14Sf of the hole diameter defining layer 14, a step (the step s of FIG. 2) between the front surface 14Sf and the adhesive layers (e.g., the adhesive layer 151 and the adhesive layer 152) is not formed. The front surface 14Sf may be disposed, for example, on approximately the same plane as the front surfaces of the adhesive layer 151 and the adhesive layer 152.

In the electronic component embedded module 10 according to the modified example, the connection hole V21 and the connection hole V22 may also be formed in the adhesive layer 151 and the adhesive layer 152 by using the inner wall 14Wi of the hole diameter defining layer 14. Therefore, the connection hole V21 and the connection hole V22 may be formed according to the shape of the inner wall 14Wi of the hole diameter defining layer 14. Therefore, the hole diameters of the connection hole V21 and the connection hole V22 may be reduced.

Also, in this electronic component embedded module 10, the process of removing the first seed layer 105 and the second seed layer 106 is unnecessary. Therefore, the number of manufacturing processes is reduced, thereby improving yield. Also, the first seed layer 105 and the second seed layer 106 may each include a metal material such as copper, titanium, or chromium. Therefore, the thermal conductivity near the connection hole V21 and the connection hole V22 may be increased, thereby improving the heat dissipation of the electronic component embedded module 10.

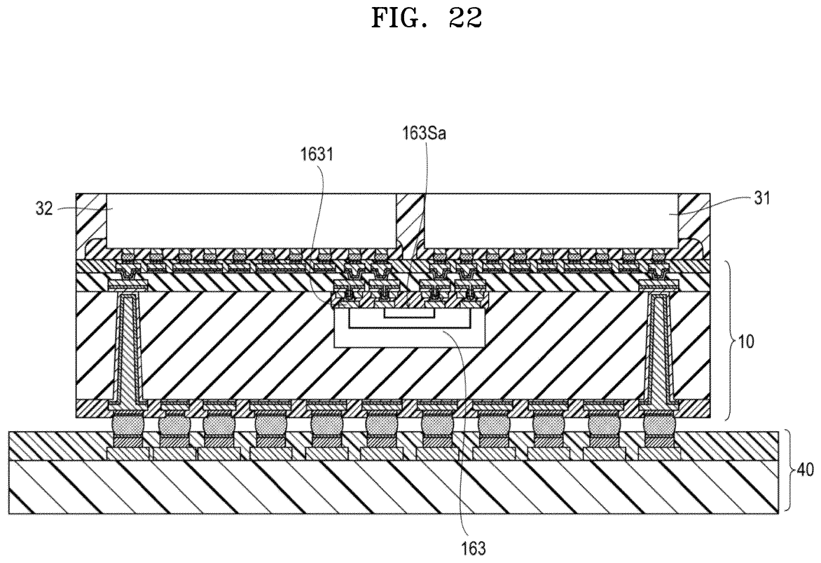

FIGS. 22 to 24 show an example of the configuration of the electronic component embedded module 10 according to other modified examples.

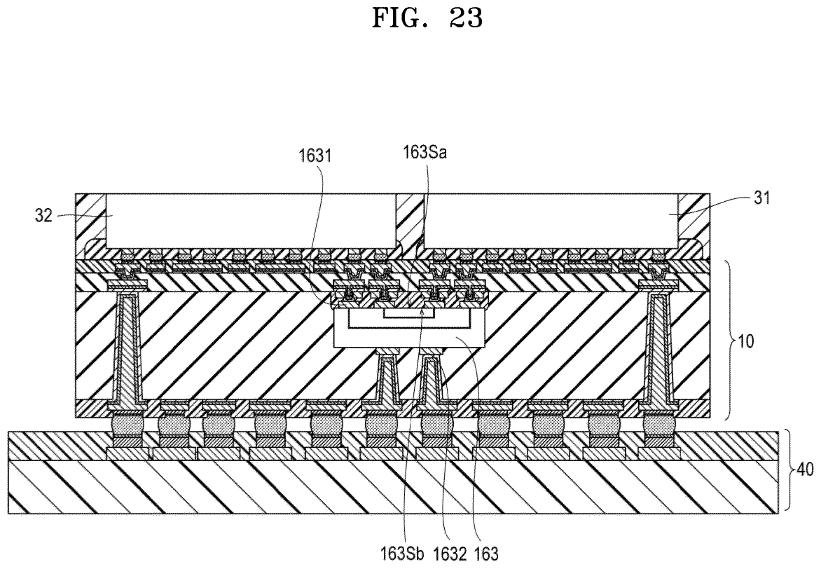

Referring to FIGS. 22 and 23, the electronic component embedded module 10 may have one electronic component (e.g., electronic component 163) embedded therein. The electronic component 163 may have only a first terminal surface 163Sa having a first terminal electrode 1631, as shown in FIG. 22. As shown in FIG. 23, the electronic component 163 may further have a second terminal surface 163Sb facing away from the first terminal surface 163Sa in the Z direction. A second terminal electrode 1632 may be provided on the second terminal surface 163Sb.

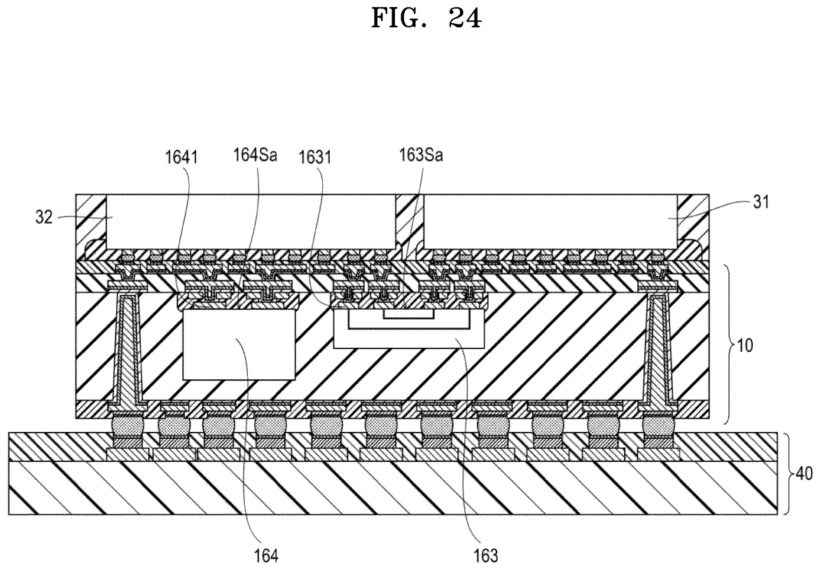

Referring to FIG. 24, the electronic component embedded module 10 may have a plurality of electronic components (e.g., the electronic component 163 and the electronic component 164) embedded therein. The electronic component 163 may have only the first terminal surface 163Sa having the first terminal electrode 131, and the electronic component 164 may have only the first terminal surface 164Sa having the first terminal electrode 1641. Since second terminal surfaces (e.g., the second terminal surface 161Sb and the second terminal surface 162Sb of FIG. 1) are not provided on electronic components, the manufacturing process of the electronic component embedded module 10 may be simplified. Also, the yield of the electronic component embedded module 10 may be improved.

FIGS. 1 and 24 show examples in which the electronic component embedded module 10 has two electronic components (e.g., the electronic component 161 and the electronic component 162 or the electronic component 163 and the electronic component 164). The electronic component embedded module 10 may have three or more electronic components.

FIG. 3 shows an example in which the hole diameter defining layer 14 and the through hole 14H have a circular or elliptical planar shape. The hole diameter defining layer 14 and the through hole 14H may have different planar shapes. For example, the hole diameter defining layer 14 and the through hole 14H may have polygonal planar shapes. The planar shape of the hole diameter defining layer 14 may be different from the planar shape of the through hole 14H.

FIG. 1 and other drawings show an example in which one connection hole (e.g., the connection hole V21 or the connection hole V22) is provided in one first terminal electrode (e.g., the first terminal electrode 1611 or the first terminal electrode 1621). A plurality of connection holes (e.g., the connection hole V21 and the connection hole V22) may be provided in one first terminal electrode (e.g., the first terminal electrode 1611 or the first terminal electrode 1621). For example, the electronic component embedded module 10 may have a plurality of the hole diameter defining layer 14 arranged in the Z direction.

Although FIGS. 4 to 20 show an example of the process of manufacturing the electronic component embedded module 10, the electronic component embedded module 10 may be manufactured through a different process. Other known techniques may be used to form each member.

The configuration of the electronic component embedded module 10 described above is an example configuration to describe features of the above-described embodiments, but is not limited to the above-described configuration, and various modifications may be made therein within the scope of embodiments of the present disclosure. Also, a configuration having provided therein a general electronic component embedded module is not excluded.

### Example Features

(1) An electronic component embedded module including a hole diameter defining layer, an electronic component, and an insulation layer, wherein the hole diameter defining layer includes an inner wall, an outer wall, a front surface intersecting the inner wall and the outer wall, and a rear surface facing away from the front surface, the electronic component includes a first terminal surface facing the rear surface of the hole diameter defining layer and a first terminal electrode provided on the first terminal surface, the insulation layer is provided between the first terminal surface and the rear surface of the hole diameter defining layer, covers the outer wall of the hole diameter defining layer, and includes a step with respect to the front surface of the hole diameter defining layer around the front surface of the hole diameter defining layer, and the electronic component embedded module further includes a connection hole extending from the inner wall of the hole diameter defining layer to the first terminal electrode through the insulation layer.
(2) The electronic component embedded module of (1) in which a portion of the insulation layer that is around the front surface of the hole diameter defining layer protrudes from the front surface of the hole diameter defining layer.
(3) An electronic component embedded module including a hole diameter

defining layer, a metal film, an electronic component, and an insulation layer, wherein the hole diameter defining layer includes an inner wall, an outer wall, a front surface intersecting with the inner wall and the outer wall, and a rear surface facing away from the front surface, the electronic component has a first terminal surface facing the rear surface of the hole diameter defining layer and a first terminal electrode provided on the first terminal surface, the insulation layer is provided between the first terminal surface and the rear surface of the hole diameter defining layer and covers the outer wall of the hole diameter defining layer, the metal film is provided on the front surface of the hole diameter defining layer and has an opening, and the electronic component embedded module further includes a connection hole extending from the opening to the first terminal electrode and through the hole diameter defining layer and the insulation layer.
(4) The electronic component embedded module of (3) in which the metal film includes at least one from among copper (Cu), titanium (Ti), and chromium (Cr).
(5) The electronic component embedded module of any one of (1) to (4) in which the hole diameter defining layer includes at least copper.
(6) The electronic component embedded module of any one of (1) to (5) further including a seed layer provided in the connection hole, and a first conductor layer electrically connected to the first terminal electrode through the seed layer.
(7) The electronic component embedded module of (6) in which the seed layer includes an adhesion film and a conductive film provided between the adhesion film and the first conductor layer, and each of the adhesion film and the conductive film includes at least one from among copper, aluminum (Al), titanium, and chromium.
(8) The electronic component embedded module of (6) or (7) in which the electronic component embedded module further includes a second conductor layer, the electronic component further includes a second terminal surface facing away from the first terminal surface, and a second terminal electrode provided on the second terminal surface, and the second terminal electrode is electrically connected to the second conductor layer.
(9) The electronic component embedded modules of any one of (1) to (8) in which the connection hole has a tapered shape.
(10) The electronic component embedded module of any one of (1) to (9) in which the hole diameter defining layer has a through hole penetrating from the front surface to the rear surface, and the inner wall defines a part of the through hole.
(11) The electronic component embedded module of (10) in which the through hole has a circular or elliptical planar shape.
(12) The electronic component embedded module of (10) or (11) in which the maximum hole diameter of the connection hole is greater than the maximum hole diameter of the through hole.
(13) The electronic component embedded module of any one of (1) to (12) in which the hole diameter defining layer includes a plating film.
(14) The electronic component embedded module of any one of (1) to (13) including a plurality of electronic components.
(15) The electronic component embedded module of (14) in which the plurality of electronic components include electronic components having different thicknesses.
(16) The electronic component embedded module of any one of (1) to (15) in which the insulation layer includes an organic insulation material.
(17) A method of manufacturing an electronic component embedded module, the method including a step (a) of forming a hole diameter defining layer having an inner wall on a support substrate, a step (b) of providing an adhesive layer covering the hole diameter defining layer on the support substrate, a step (c) of attaching an electronic component having a terminal electrode on a terminal surface to the support substrate through the adhesive layer such that the terminal surface faces the support substrate, a step (d) of removing the support substrate after the electronic component is attached to the support substrate, a step (e) of forming a connection hole reaching the terminal electrode from the inner wall through the adhesive layer, a step (f) of forming a seed layer in the connection hole, and a step (g) of electrically connecting a conductor layer and the terminal electrode through the seed layer.
(18) The method of (17) in which, in the step (f), the seed layer is formed in the connection hole by using a sputtering method.
(19) The method of (18) in which, in the step (a), the hole diameter defining layer is formed on the support substrate by using an electrolytic plating method.
(20) The method of any one of (17) to (19) in which the support substrate includes glass.

While non-limiting example embodiments have been particularly shown and described, it will be understood that various changes in form and details may be made therein without departing from the spirit and scope of the present disclosure.

What is claimed is:

1. An electronic component embedded module comprising:
a hole diameter defining layer;
an electronic component; and
an insulation layer,
wherein the hole diameter defining layer comprises an inner wall, an outer wall, a front surface intersecting with the inner wall and the outer wall, and a rear surface facing away from the front surface,
wherein the electronic component comprises:
a first terminal surface facing the rear surface of the hole diameter defining layer; and
a first terminal electrode on the first terminal surface,
wherein the insulation layer is between the first terminal surface and the rear surface of the hole diameter defining layer, covers the outer wall of the hole diameter defining layer, and comprises a step with respect to the front surface of the hole diameter defining layer around the front surface of the hole diameter defining layer, and
wherein a connection hole extends from the inner wall of the hole diameter defining layer to the first terminal electrode through the insulation layer.

2. The electronic component embedded module of claim 1, wherein a portion of the insulation layer that is around the front surface of the hole diameter defining layer protrudes from the front surface of the hole diameter defining layer.

3. The electronic component embedded module of claim 1, wherein the hole diameter defining layer comprises copper.

4. The electronic component embedded module of claim 1, wherein the hole diameter defining layer includes a through hole penetrating from the front surface of the hole diameter defining layer to the rear surface of the hole diameter defining layer, and
wherein the inner wall of the hole diameter defining layer defines a part of the through hole.

5. The electronic component embedded module of claim 4, wherein the through hole comprises a circular or elliptical planar shape.

6. The electronic component embedded module of claim 4, wherein a maximum hole diameter of the connection hole is greater than a maximum hole diameter of the through hole.

7. The electronic component embedded module of claim 1, wherein the insulation layer comprises an organic insulation material.

8. An electronic component embedded module comprising:
a hole diameter defining layer;
a metal film;
an electronic component; and
an insulation layer,
wherein the hole diameter defining layer comprises an inner wall, an outer wall, a front surface intersecting with the inner wall and the outer wall, and a rear surface facing away from the front surface,
wherein the electronic component comprises:
a first terminal surface facing the rear surface of the hole diameter defining layer; and
a first terminal electrode on the first terminal surface,
wherein the insulation layer is between the first terminal surface and the rear surface of the hole diameter defining layer and covers the outer wall of the hole diameter defining layer,
wherein the metal film is on the front surface of the hole diameter defining layer and includes an opening, and
wherein a connection hole extends from the opening to the first terminal electrode and through the hole diameter defining layer and the insulation layer.

9. The electronic component embedded module of claim 8, wherein the metal film comprises at least one from among copper (Cu), titanium (Ti), and chromium (Cr).

10. The electronic component embedded module of claim 8, further comprising:
a seed layer in the connection hole; and
a first conductor layer electrically connected to the first terminal electrode via the seed layer.

11. The electronic component embedded module of claim 10, wherein the seed layer comprises an adhesion film and a conductive film between the adhesion film and the first conductor layer, and
wherein each of the adhesion film and the conductive film comprises at least one from among copper, aluminum (Al), titanium, and chromium.

12. The electronic component embedded module of claim 10, further comprising a second conductor layer,
wherein the electronic component further comprises a second terminal surface facing away from the first terminal surface, and a second terminal electrode on the second terminal surface, and
wherein the second terminal electrode is electrically connected to the second conductor layer.

13. The electronic component embedded module of claim 8, wherein the connection hole comprises a tapered shape.

14. The electronic component embedded module of claim 8, wherein the hole diameter defining layer comprises a plating film.

15. The electronic component embedded module of claim 8, further comprising an additional electronic component.

16. The electronic component embedded module of claim 15, wherein the electronic component has a thickness different from a thickness of the additional electronic component.

17. An electronic device comprising:
a mounting substrate;
an electronic component embedded module on the mounting substrate; and
a semiconductor element on the electronic component embedded module,
wherein the electronic component embedded module comprises:
a hole diameter defining layer comprising an inner wall, an outer wall, a front surface intersecting with the inner wall and the outer wall, and a rear surface facing away from the front surface;
an electronic component comprising:
a first terminal surface facing the rear surface of the hole diameter defining layer; and
a first terminal electrode on the first terminal surface;
an insulation layer between the first terminal surface and the rear surface of the hole diameter defining layer, covering the outer wall of the hole diameter defining layer, and comprising a step with respect to the front surface of the hole diameter defining layer around the front surface of the hole diameter defining layer, and
wherein a connection hole extends from the inner wall of the hole diameter defining layer to the first terminal electrode through the insulation layer.

18. The electronic device of claim 17, wherein the electronic component embedded module further comprises a metal film on the front surface of the hole diameter defining layer and including an opening.

19. The electronic device of claim 17, wherein a maximum hole diameter of the connection hole is greater than a maximum hole diameter of the hole diameter defining layer.

20. The electronic device of claim 17, wherein a hole diameter of the connection hole is greatest at a position adjacent to the rear surface of the hole diameter defining layer.
